(19) United States
(12) Patent Application Publication
(10) Pub. No.: US 2024/0365528 A1
(43) Pub. Date: Oct. 31, 2024

(54) INTEGRATED CIRCUIT INCLUDING BACKSIDE WIRES

(71) Applicant: SAMSUNG ELECTRONICS CO., LTD., Suwon-si (KR)

(72) Inventors: Changhoon SUNG, Suwon-si (KR); Hyojin Cho, Suwon-si (KR); Hoyoung Tang, Suwon-si (KR); Taehyung Kim, Suwon-si (KR); Eojin Lee, Suwon-si (KR)

(73) Assignee: SAMSUNG ELECTRONICS CO., LTD., Suwon-si (KR)

(21) Appl. No.: 18/643,224

(22) Filed: Apr. 23, 2024

(30) Foreign Application Priority Data
Apr. 26, 2023 (KR) 10-2023-0054977
Aug. 17, 2023 (KR) 10-2023-0107916

(51) Int. Cl. H10B 10/00; G11C 5/06; H01L 23/528; H01L 27/092; H01L 29/06; H01L 29/423; H01L 29/775; H01L 29/78; H01L 29/786

(52) U.S. Cl. CPC H10B 10/125; G11C 5/063; H01L 23/5283; H01L 27/0924; H01L 29/0673; H01L 29/42392; H01L 29/775; H01L 29/7851; H01L 29/78696

(57) ABSTRACT

An integrated circuit is provided and includes a memory cell array, a plurality of gate electrodes extending in a first direction above a substrate, a plurality of word lines extending in the first direction above the substrate, a plurality of bit lines extending below the substrate in a second direction intersecting the first direction, and a plurality of first contacts passing through the substrate in a vertical direction and respectively connected to the plurality of bit lines.

### CROSS-REFERENCE TO RELATED APPLICATIONS

This application is based on and claims priority under 35 U.S.C. § 119 to Korean Patent Application Nos. 10-2023-0054977, filed on Apr. 26, 2023, and 10-2023-0107916, filed on Aug. 17, 2023, in the Korean Intellectual Property Office, the disclosures of which are incorporated by reference herein in their entireties.

### BACKGROUND

Embodiments of the present disclosure relate to an integrated circuit, and more particularly, to an integrated circuit including backside wires.

Due to the need for high integration and advancements in semiconductor processes, the widths, spacings, and/or heights of wires included in an integrated circuit may decrease, and thus, the influence of parasitic elements of the wires may increase. Also, a power supply voltage of an integrated circuit may be reduced for reduced power consumption, high operating speed, etc., and thus, the influence of parasitic components of wires on the integrated circuit may become more significant. Despite such parasitic elements, an integrated circuit including a cell array including cells of the same structure may be demanded to robustly provide high integration and performance according to the requirements of various applications.

### SUMMARY

According to embodiments of the present disclosure, an integrated circuit is provided and includes a cell array routed by backside wires.

According to embodiments of the present disclosure, an integrated circuit is provided and includes: a memory cell array; a plurality of gate electrodes extending in a first direction above a substrate; a plurality of word lines extending in the first direction above the substrate; a plurality of bit lines extending below the substrate in a second direction intersecting the first direction; and a plurality of first contacts passing through the substrate in a vertical direction and respectively connected to the plurality of bit lines.

According to embodiments of the present disclosure, an integrated circuit is provided and includes: a memory cell array; a plurality of gate electrodes extending in a first direction above a substrate; a plurality of bit lines extending above the substrate in a second direction intersecting the first direction; a plurality of word lines extending in the first direction below the substrate; and a plurality of contacts passing through the substrate in a vertical direction and respectively connected to the plurality of gate electrodes and the plurality of word lines.

According to embodiments of the present disclosure, an integrated circuit is provided and includes: a memory cell array; a plurality of gate electrodes extending in a first direction above a substrate; a plurality of word lines extending in the first direction above the substrate; a plurality of bit lines extending above the substrate in a second direction intersecting the first direction; a plurality of first power lines extending below the substrate in the second direction and configured to receive a first supply voltage; a plurality of second power lines extending below the substrate in the second direction and configured to receive a second supply voltage; and a plurality of contacts passing through the substrate in a vertical direction and respectively connected to the plurality of first power lines and the plurality of second power lines.

According to embodiments of the present disclosure, an integrated circuit is provided and includes: a memory cell array including a plurality of memory cells; a plurality of gate electrodes extending in a first direction above a substrate; a plurality of word lines extending in the first direction above the substrate; a plurality of bit lines extending above the substrate in a second direction intersecting the first direction; and a plurality of first contacts, each including a first portion extending under the substrate in the second direction, wherein each of the plurality of memory cells included in the memory cell array includes a first inverter and a second inverter that are cross-coupled with each other at a first node and a second node, and wherein each of the plurality of first contacts is electrically connected to the first node or the second node.

### BRIEF DESCRIPTION OF DRAWINGS

Embodiments of the present disclosure will be more clearly understood from the following detailed description taken in conjunction with the accompanying drawings in which:

FIGS. 1A and 1B are diagrams showing layouts of an integrated circuit according to an embodiment;

FIGS. 2A to 2D are diagrams showing examples of devices according to embodiments;

FIG. 3 is a block diagram showing an integrated circuit according to an embodiment;

FIG. 4 is a circuit diagram showing a memory cell according to an embodiment;

FIGS. 5A to 5C are diagrams showing layouts of an integrated circuit according to embodiments;

FIGS. 6A and 6B are diagrams showing layouts of an integrated circuit according to embodiments;

FIGS. 7A to 7C are diagrams showing layouts of an integrated circuit according to embodiments;

FIG. 8 is a diagram showing the layout of an integrated circuit according to an embodiment;

FIGS. 9A to 9C are diagrams showing layouts of an integrated circuit according to embodiments;

FIGS. 10A and 10B are diagrams showing layouts of an integrated circuit according to embodiments;

FIG. 11 is a flowchart of a method of manufacturing an integrated circuit according to an embodiment;

FIG. 12 is a flowchart of a method of designing an integrated circuit according to an embodiment;

FIG. 13 is a block diagram showing a system-on-chip according to an embodiment; and

FIG. 14 is a block diagram showing a computing system including a memory storing a program according to an embodiment.

### DETAILED DESCRIPTION

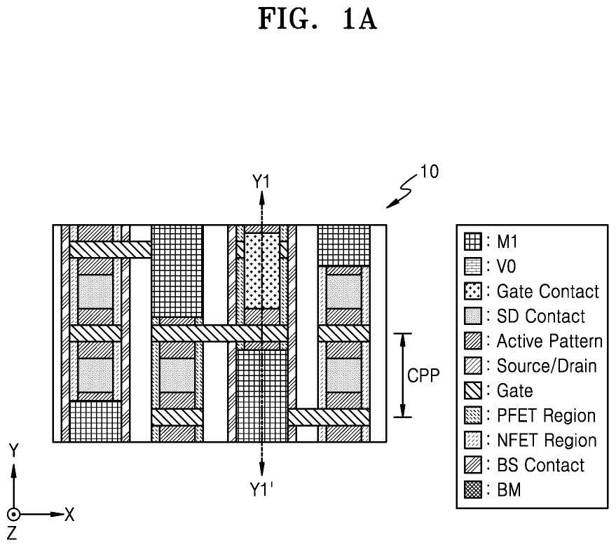

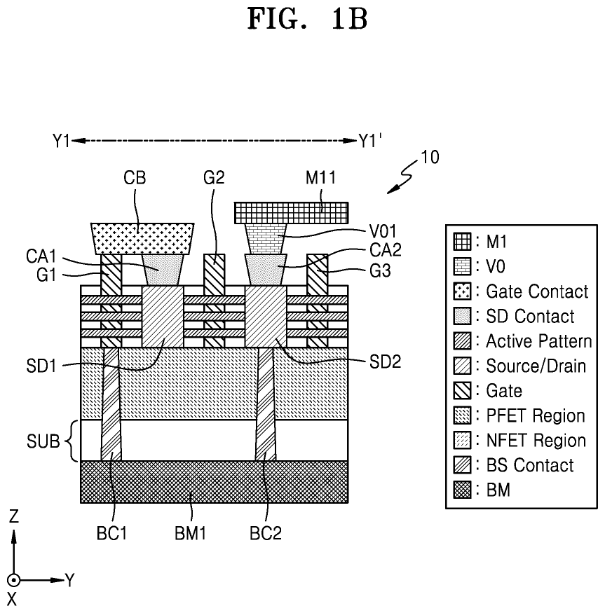

FIGS. 1A and 1B are diagrams showing layouts of an integrated circuit 10 according to an embodiment. For example, FIG. 1A is a plan view of the layout of the integrated circuit 10 in the −Z-axis direction, and FIG. 1B is a cross-sectional view of the layout of the integrated circuit 10 taken along a line Y1-Y1′ of FIG. 1A.

Herein, the X-axis direction and the Y-axis direction may each be referred to as a horizontal direction, and the Z-axis direction may be referred to as a vertical direction. A plane including an X-axis and a Y-axis may be referred to as a horizontal plane, components placed in the +Z-axis direction relative to other components may be referred to as being above the other components, and components placed in the −Z-axis direction relative to other components may be referred to as being below the other components. Also, an area of a component may refer to a size occupied by the component in a plane parallel to the horizontal plane, and a width of a component may refer to a length of the component in a direction perpendicular to the direction in which the component extends. A surface exposed in the +Z-axis direction may be referred to as a top surface, a surface exposed in the −Z-axis direction may be referred to as a bottom surface, and a surface exposed in the +X direction or the +Y direction may be referred to as a side surface. For convenience of illustration, only some layers may be shown in the drawings, and a via interconnecting an upper pattern and a lower pattern may be shown in the upper pattern for understanding even though it is located below the upper pattern. Further, a pattern including or consisting of a conductive material like a pattern of a wiring layer may be referred to as a conductive pattern or may be simply referred to as a pattern.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

Referring to FIG. 1A, the integrated circuit 10 may include gate lines (or gate electrodes) extending in the X-axis direction and may include p-channel field effect transistor (PFET) regions and n-channel field effect transistor (NFET) regions extending in the Y-axis direction. As shown in FIG. 1A, the pitch of the gate lines may be referred to as a contact-poly-pitch (CPP). At least one active pattern may extend in the Y-axis direction in each of the PFET regions and the NFET regions, and the at least one active pattern and a gate line may form a transistor. For example, as shown in FIG. 1B, three active patterns may extend in the Y-axis direction in the PFET regions, and the three active patterns, a first gate line G1, a second gate line G2, and a third gate line G3 (e.g., gate electrodes) may form PFETs.

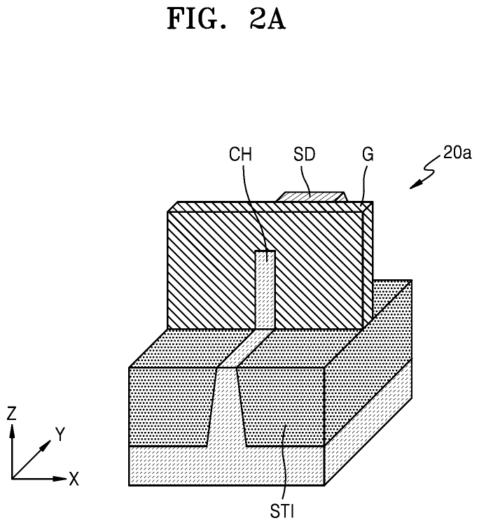

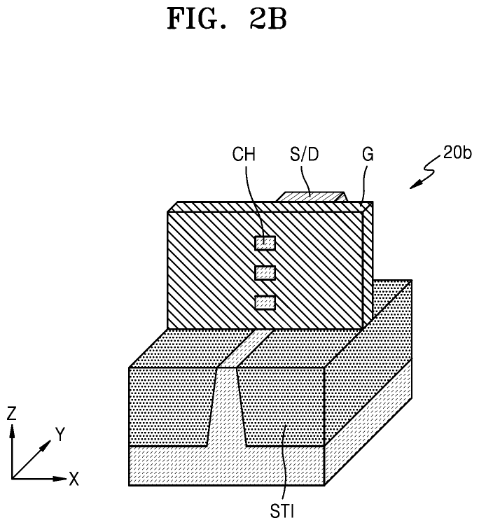

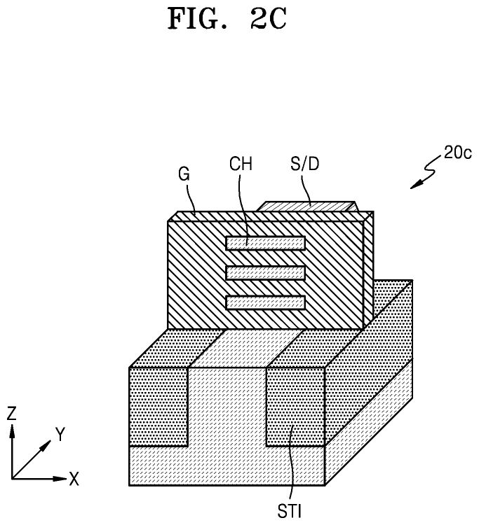

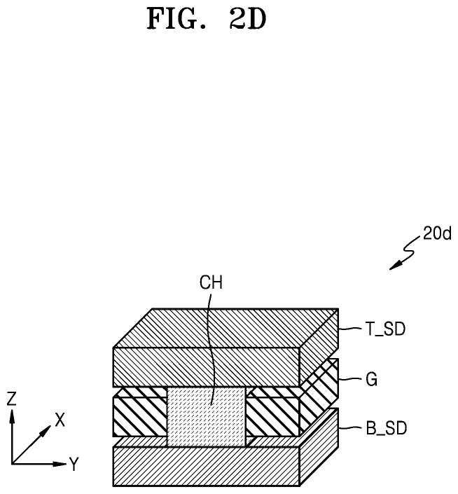

Source/drains may be placed on both sides of a gate line, and source/drain contacts (SD contacts or S/D contacts) may be placed on the source/drains. For example, as shown in FIG. 1B, a first source/drain SD1 and a second source/drain SD2 may be placed on both sides of a second gate line G2 (e.g., second gate electrode). A channel may be formed below a gate line between sources/drains. Examples of the channel will be described later with reference to FIGS. 2A to 2D. A via of a first via layer V0 may be disposed on a source/drain contact, and the via may be connected to the source/drain contact and a pattern of a first wiring layer M1. For example, as shown in FIG. 1B, a second source/drain contact CA2 may be disposed on the second source/drain SD2, and a via V01 connected to a pattern M11 of the first wiring layer M1 may be disposed on the second source/drain contact CA2.

A gate contact may be formed on a gate line. The gate contact may extend in the Y-axis direction and may be connected to a source/drain contact. For example, as shown in FIG. 1B, a gate contact CB may be disposed on a first gate line G1 (e.g., first gate electrode), extend in the Y-axis direction, and may be connected to a first source/drain contact CA1. According to some embodiments, a via of the first via layer V0 may be disposed on a gate contact, and the via may be connected to the gate contact and the pattern of the first wiring layer M1. According to some embodiments, the gate contact may be directly connected to the pattern of the first wiring layer M1. Herein, the source/drain contact and the gate contact may be referred to as front side contacts or simply as contacts.

The integrated circuit 10 may include patterns extending in a backside wiring layer below a substrate SUB. For example, as shown in FIG. 1B, a first backside pattern BM1 in a backside wiring layer BM may extend in the Y-axis direction below the substrate SUB. According to some embodiments, the substrate SUB may include an insulation layer extending in horizontal directions to insulate the PFET regions (or the NFET regions) and the backside wiring layer BM from each other, such as a nitride-based backside inter-layer dielectric (ILD).

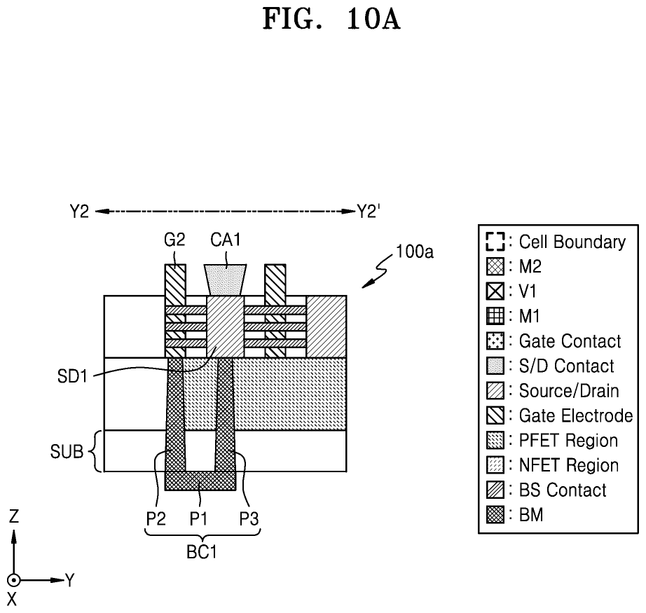

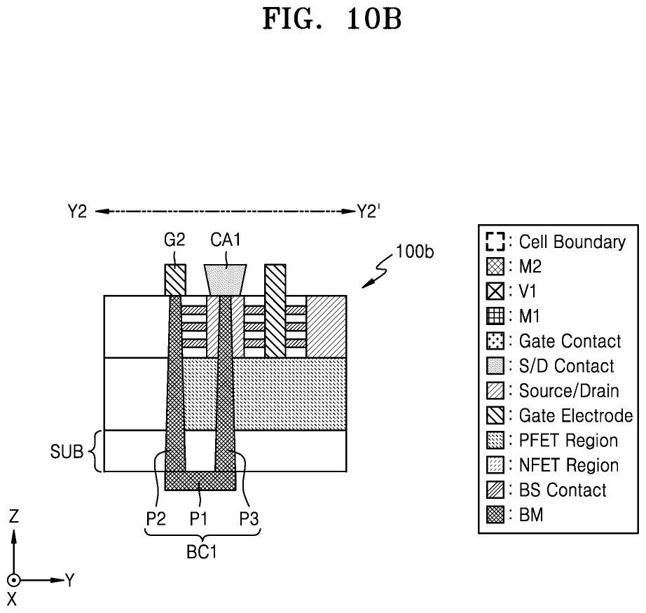

The integrated circuit 10 may include a backside contact that passes through the substrate SUB in a vertical direction. For example, as shown in FIG. 1B, a first backside contact BC1 may have a bottom surface connected to the first backside pattern BM1 and a top surface connected to the first gate line G1 (e.g., first gate electrode). A second backside contact BC2 may have a bottom surface connected to the first backside pattern BM1 and a top surface connected to the second source/drain SD2. Herein, the first backside contact BC1 may be referred to as a backside gate contact, and the second backside contact BC2 may be referred to as a backside source/drain contact. According to some embodiments, as described below with reference to FIG. 10B, a backside contact may pass through active patterns or source/drains and may be connected to a source/drain contact.

FIGS. 2A to 2D are diagrams showing examples of devices according to embodiments. For example, FIG. 2A shows a fin field-effect transistor (FinFET) 20a, FIG. 2B shows a gate-all-around field effect transistor (GAAFET) 20b, FIG. 2C shows a multi-bridge channel field effect transistor (MBCFET) 20c, and FIG. 2D shows a vertical field effect transistor (VFET) 20d. For convenience of illustration, FIGS. 2A to 2C show structures in which one of two source/drain regions is removed, and FIG. 2D shows a cross-section of the VFET 20d cut along the plane parallel to the plane consisting of the Y axis and the Z axis and passing through a channel CH of the VFET 20d.

Referring to FIG. 2A, the FinFET 20a may be formed by a fin-type active pattern extending in the Y-axis direction between shallow trench isolations (STIs) and a gate electrode G extending in the X-axis direction. A source/drain region SD may be formed on both sides of the gate electrode G, and thus a source and a drain may be spaced apart from each other in the Y-axis direction. An insulation layer may be formed between the channel CH and the gate electrode G. According to some embodiments, the FinFET 20a may be formed by the gate electrode G and a plurality of active patterns spaced apart from each other in the X-axis direction and may have an expanded channel.

Referring to FIG. 2B, the GAAFET 20b may be formed by active patterns (i.e., nanowires) extending in the Y-axis direction and spaced apart from each other in the Z-axis direction and the gate electrode G extending in the X-axis direction. A source/drain region SD may be formed on both sides of the gate electrode G, and thus a source and a drain may be spaced apart from each other in the Y-axis direction. An insulation layer may be formed between the channel CH and the gate electrode G. The number of nanowires included in the GAAFET 20b is not limited to the number of nanowires shown in FIG. 2B.

Referring to FIG. 2C, the MBCFET 20c may be formed by active patterns (i.e., nano-sheets) extending in the Y-axis direction and spaced apart from each other in the Z-axis direction and the gate electrode G extending in the X-axis direction. A source/drain region SD may be formed on both sides of the gate electrode G, and thus a source and a drain may be spaced apart from each other in the Y-axis direction. An insulation layer may be formed between the channel CH and the gate electrode G. The number of nano-sheets included in the MBCFET 20c is not limited to the number of nano-sheets shown in FIG. 2C.

Referring to FIG. 2D, the VFET 20d may include a top source/drain region T_SD and a bottom source/drain region B_SD spaced apart from each other in the Z-axis direction with the channel CH therebetween. The VFET 20d may include the gate electrode G surrounding the circumference of the channel CH between the top source/drain region T_SD and the bottom source/drain region B_SD. An insulation layer may be formed between the channel CH and the gate electrode G.

Hereinafter, an integrated circuit including the FinFET 20a or the MBCFET 20c will be mainly described, but it is noted that devices included in an integrated circuit are not limited to the examples of FIGS. 2A to 2D. For example, an integrated circuit may include a ForkFET in which nano-sheets for a P-type transistor and nano-sheets for an N-type transistor are separated from each other by a dielectric wall, and thus an N-type transistor and a P-type transistor have structures closer to each other. Also, an integrated circuit may include bipolar junction transistors as well as FETs, such as a complementary field effect transistor (CFET), a negative capacitance field effect transistor (NCFET), and a carbon nanotube (CNT) FET.

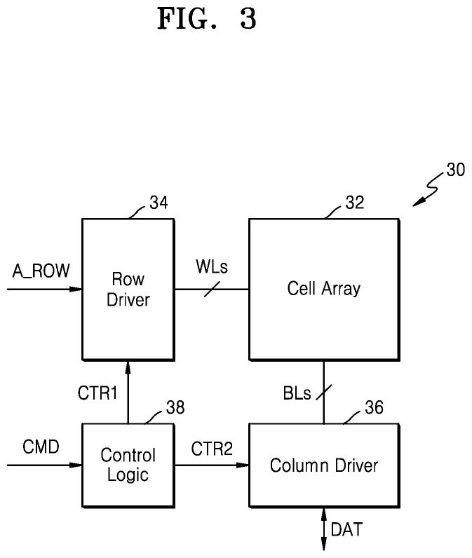

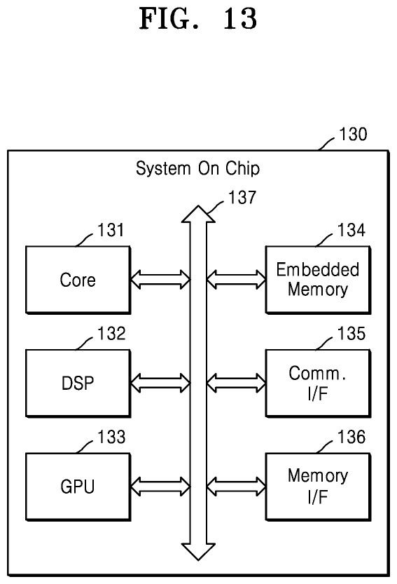

FIG. 3 is a block diagram showing an integrated circuit according to an embodiment. For example, the block diagram of FIG. 3 shows a memory device 30 included in the integrated circuit. According to some embodiments, the memory device 30 may be a standalone memory device and may store data based on commands and addresses provided from outside of an integrated circuit. Also, according to some embodiments, the integrated circuit may be an embedded memory device and may further include other components for writing data to or reading data from the memory device 30, as will be described later with reference to FIG. 13. As shown in FIG. 3, the memory device 30 may include a cell array 32, a row driver 34, a column driver 36, and a control logic 38. Components of the memory device 30 excluding the cell array 32, that is, the row driver 34, column driver 36, and control logic 38, may be collectively referred to as peripheral circuits. According to some embodiments, the memory device 30 may further include an address buffer, a data buffer, and a data input/output circuit.

The memory device 30 may receive a command CMD, an address, and data DAT. For example, the memory device 30 may receive a command CMD instructing write, an address, and the data DAT, and store the received data DAT in a region of the cell array 32 corresponding to the address. Also, the memory device 30 may receive a command CMD instructing read and an address, and output data stored in a region of the cell array 32 corresponding to the address to the outside.

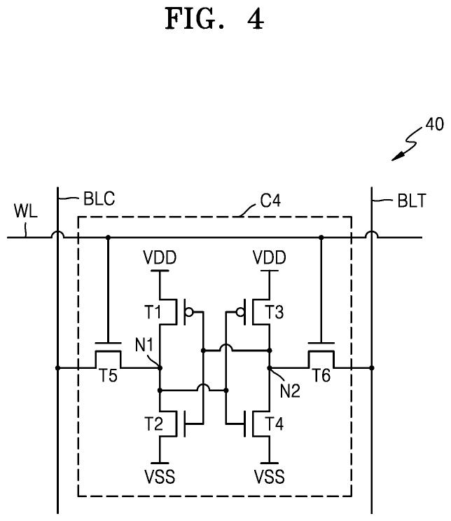

The cell array 32 may include a plurality of memory cells each accessed by a word line and a bit line. According to some embodiments, the memory cells included in the cell array 32 may be volatile memory cells, such as static random access memory (SRAM) cells, dynamic random access memory (DRAM) cells, etc. According to some embodiments, the memory cells included in the cell array 32 may be non-volatile memory cells, such as flash memory cells, resistive random access memory (RRAM) cells, etc. Embodiments of the present disclosure will be described primarily with reference to SRAM cells, as described below with reference to FIG. 4 and the like. However, embodiments are not limited thereto. Herein, the cell array 32 may be referred to as a memory cell array, and memory cells may be referred to simply as cells.

The row driver 34 may be connected to the cell array 32 through a plurality of word lines WLs. The row driver 34 may activate one word line from among the plurality of word lines WLs based on a row address A_ROW. Therefore, from among the memory cells included in the cell array 32, memory cells connected to an activated word line (i.e., memory cells arranged in a row corresponding to the activated word line) may be selected. By the column driver 36, which will be described later, the data DAT may be written into selected memory cells during a write operation or the data DAT may be read from selected memory cells during a read operation.

The column driver 36 may be connected to the cell array 32 through a plurality of bit lines BLs. The column driver 36 may detect a current and/or voltage received through the plurality of bit lines BLs during a read operation, thereby identifying values stored in memory cells connected to an activated word line (i.e., selected memory cells) and output the data DAT based on identified values. Also, the column driver 36 may apply a current and/or a voltage to the plurality of bit lines BLs based on the data DAT during a write operation and may write values to memory cells connected to an activated word line (i.e., selected memory cells).

The control logic 38 may receive the command CMD and generate a first control signal CTR1 and a second control signal CTR2. For example, the control logic 38 may identify a read command by decoding the command CMD and generate the first control signal CTR1 and the second control signal CTR2 to read the data DAT from the cell array 32. Also, the control logic 38 may identify a write command by decoding the command CMD and generate the first control signal CTR1 and the second control signal CTR2 to write the data DAT to the cell array 32. According to some embodiments, the row driver 34 may activate or deactivate a word line at a timing determined based on the first control signal CTR1. Also, according to some embodiments, the column driver 36 may detect a current and/or a voltage in the plurality of bit lines BLs or apply a current and/or a voltage to the plurality of bit lines BLs at a timing determined based on the second control signal CTR2.

FIG. 4 is a circuit diagram showing a memory cell according to an embodiment. For example, the circuit diagram of FIG. 4 shows an equivalent circuit 40 corresponding to one memory cell C4 included in the cell array 32 of FIG. 3. According to some embodiments, the cell array 32 may include memory cells having the structure identical to the structure of the memory cell C4. Hereinafter, FIG. 4 will be described with reference to FIG. 3.

Referring to FIG. 4, the memory cell C4 may be connected to a word line WL, and memory cells arranged in the same row as the memory cell C4 may be commonly connected to the word line WL. Also, the memory cell C4 may be connected to a bit line BLC and a complementary bit line BLT, and memory cells arranged in the same column as the memory cell C4 may be commonly connected to the bit line BLC and the complementary bit line BLT. Herein, the bit line BLC and the complementary bit line BLT may be referred to as a first bit line and a second bit line, respectively, and a plurality of first bit lines and a plurality of second bit lines may be alternately arranged.

The memory cell C4 may include a first transistor T1, a second transistor T2, a third transistor T3, a fourth transistor T4, a fifth transistor T5, and a sixth transistor T6, and may be referred to as a 6T SRAM cell. As shown in FIG. 4, the first transistor T1 and the third transistor T3 may be PFETs, and the second transistor T2, the fourth transistor T4, the fifth transistor T5, and the sixth transistor T6 may be NFETs. The memory cell C4 may include a cross-coupled inverter pair between a node to which a positive supply voltage VDD is applied and a node to which a negative supply voltage (or ground potential) VSS is applied. For example, a first inverter and a second inverter may be cross-coupled at a first node N1 and a second node N2, the first inverter may include the first transistor T1 and the second transistor T2, and the second inverter may include the third transistor T3 and the fourth transistor T4.

The fifth transistor T5 and the sixth transistor T6 may electrically connect the first inverter and the second inverter to the bit line BLC and the complementary bit line BLT, respectively, by an activated word line WL (e.g., the word line WL having a high-level voltage). For example, the fifth transistor T5 may be connected to the first node N1 to which an output of the first inverter and an input of the second inverter are connected and may electrically connect the first node N1 to the bit line BLC in response to the activated word line WL. Also, the sixth transistor T6 may be connected to the second node N2 to which an input of the first inverter and an output of the second inverter are connected and may electrically connect the second node N2 to the complementary bit line BLT in response to the activated word line WL. Herein, the fifth transistor T5 and the sixth transistor T6 may be referred to as pass transistors.

Due to advancements in semiconductor processes, the size of transistors may be reduced and the size of memory cells may be reduced. Also, routing resources may be limited not only for patterns corresponding to the word line WL, the bit line BLC, and the complementary bit line BLT connected to memory cells, but also for patterns for providing the positive supply voltage VDD or the negative supply voltage VSS to the memory cells. Therefore, parasitic elements of the pattern, such as parasitic resistance and/or parasitic capacitance, may increase, and performance and reliability of a memory device may be limited. For example, when a voltage drop occurs at the positive supply voltage VDD and the negative supply voltage VSS due to parasitic resistance, the memory cell C4 may not properly output a signal corresponding to a value latched to a cross-coupled inverter pair to the bit line BLC and the complementary bit line BLT, and may not properly latch a value corresponding to a signal applied to the bit line BLC and the complementary bit line BLT to the cross-coupled inverter pair. Also, as the number of memory cells increases, the word line WL may be extended, and the influence of parasitic resistance on the word line WL may increase. Therefore, a memory cell located far from the row driver 34 of FIG. 3 may identify activation of a word line at a delayed time point, and thus the operation speed of the memory device 30 of FIG. 3 may be limited.

As will be described later with reference to the drawings, the cell array 32 may include patterns extending in a backside wiring layer below a substrate and backside contacts passing through the substrate in a vertical direction. Patterns extending in the backside wiring layer may be used for routing of supply voltages (e.g., VDD and VSS) or signals (e.g., word line WL, bit line BLC, complementary bit line BLT, first node N1, and second node N2). Therefore, routing resources may be increased in the cell array 32 and parasitic elements of patterns may be reduced, and thus performance and reliability of the memory device 30 may be improved.

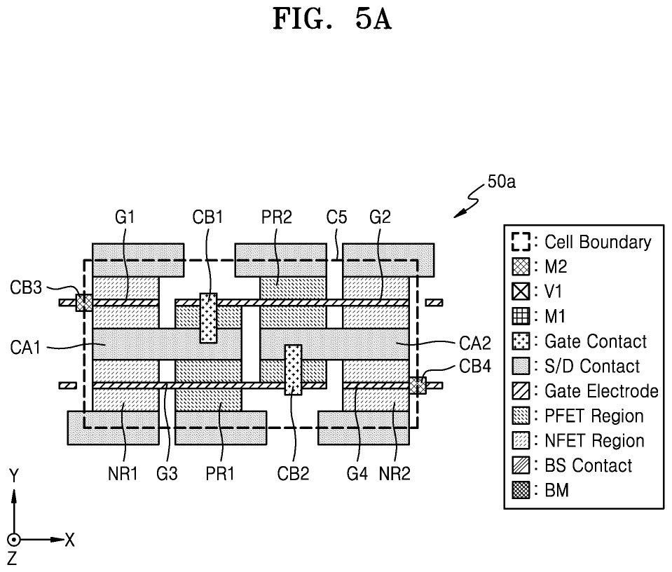

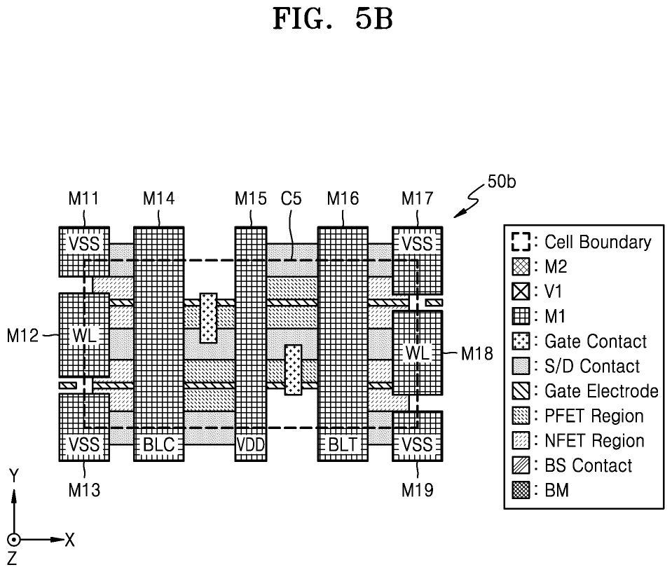

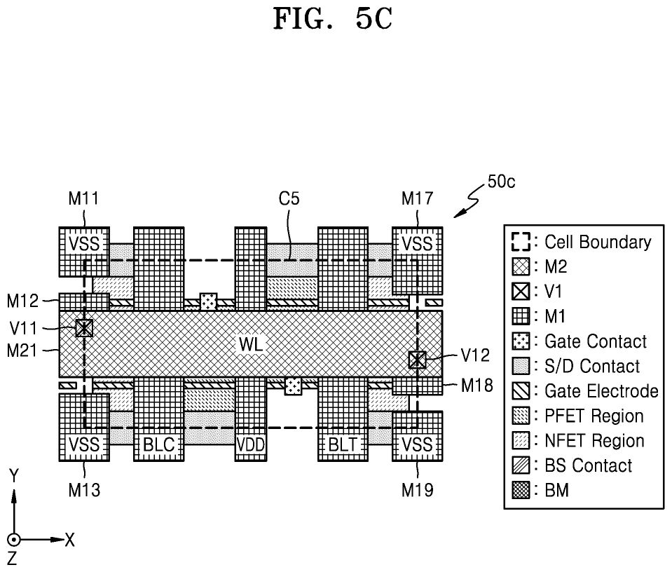

FIGS. 5A to 5C are diagrams showing a layout 50a, a layout 50b, and a layout 50c of an integrated circuit according to embodiments. For example, the plan views of FIGS. 5A to 5C show the layout 50a, the layout 50b, and the layout 50c of a memory cell C5 corresponding to the equivalent circuit 40 of FIG. 4. The plan view of FIG. 5A shows a layout 50a including NFET regions, PFET regions, gate electrodes, and contacts, the plan view of FIG. 5B shows a layout 50b further including patterns of the first wiring layer M1 as compared to the layout 50a of FIG. 5A, and the plan view of FIG. 5C shows a layout 50c further including vias of a via layer V1 and patterns of a second wiring layer M2 as compared to the layout 50b of FIG. 5B. In FIGS. 5A to 5C, a name written on a pattern indicates a voltage applied to a line to which the pattern is electrically connected and/or the pattern. For convenience of illustration, source/drains and active patterns are omitted in FIGS. 5A to 5C. Hereinafter, FIGS. 5A to 5C will be described with reference to FIG. 4.

Referring to FIG. 5A, gate electrodes may extend in the X-axis direction, and NFET regions and PFET regions may extend in the Y-axis direction. For example, a first gate line G1, a second gate line G2, a third gate line G3, and a fourth gate line G4 (e.g., gate electrodes) may extend in the X-axis direction, and a first NFET region NR1, a second NFET region NR2, a first PFET region PR1, and a second PFET region PR2 may extend in the Y-axis direction. The first gate line G1 may form the fifth transistor T5 of FIG. 4 in the first NFET region NR1 and may be electrically connected to a second pattern M12 of FIG. 5B through a third gate contact CB3. The second gate line G2 may form the third transistor T3 in the second PFET region PR2 and form the fourth transistor T4 in the second NFET region NR2. The third gate line G3 may form the second transistor T2 in the first NFET region NR1 and form the first transistor T1 in the first PFET region PR1. The fourth gate line G4 may form the sixth transistor T6 in the second NFET region NR2 and may be electrically connected to an eighth pattern M18 of FIG. 5B through a fourth gate contact CB4.

Source/drain contacts may extend in the X-axis direction, and gate contacts may extend in the Y-axis direction. For example, as shown in FIG. 5A, the first source/drain contact CA1 may extend in the X-axis direction above the first NFET region NR1 and the first PFET region PR1, and the second source/drain contact CA2 may extend in the X-axis direction above the second PFET region PR2 and the second NFET region NR2. Also, a first gate contact CB1 may extend in the Y-axis direction on the second gate electrode G2 and be connected to the first source/drain contact CA1. A second gate contact CB2 may extend in the Y-axis direction on the third gate electrode G3 and be connected to the second source/drain contact CA2. Therefore, the first source/drain contact CA1 and the first gate contact CB1 may correspond to the first node N1, and the second source/drain contact CA2 and the second gate contact CB2 may correspond to the second node N2.

Referring to FIG. 5B, patterns may extend in the Y-axis direction in the first wiring layer M1. For example, as shown in FIG. 5B, a fourth pattern M14 and a sixth pattern M16 respectively corresponding to the bit line BLC and the complementary bit line BLT may extend in the Y-axis direction. A fifth pattern M15 corresponding to the positive supply voltage VDD may extend in the Y-axis direction between the fourth pattern M14 and the sixth pattern M16. Also, a first pattern M11, a third pattern M13, a seventh pattern M17, and a ninth pattern M19 corresponding to the negative supply voltage VSS may extend in the Y-axis direction. The second pattern M12 corresponding to the word line WL may extend in the Y-axis direction between the first pattern M11 and the third pattern M13, and the eighth pattern M18 corresponding to the word line WL may extend in the Y-axis direction between the seventh pattern M17 and the ninth pattern M19.

Referring to FIG. 5C, patterns may extend in the X-axis direction in the second wiring layer M2. For example, as shown in FIG. 5C, a pattern M21 corresponding to the word line WL in the second wiring layer M2 may extend in the X-axis direction. The pattern M21 may be electrically connected to the second pattern M12 of the first wiring layer M1 through a first via V11 of a second via layer V1 and may be electrically connected to the eighth pattern M18 of the first wiring layer M1 through a second via V12 of the second via layer V1. According to some embodiments, patterns for electrically connecting patterns of the first wiring layer M1 corresponding to the negative supply voltage VSS to each other may extend in the X-axis direction in the second wiring layer M2. For example, a pattern of the second wiring layer M2 for electrically connecting the first pattern M11 and the seventh pattern M17 may extend in the X-axis direction, and a pattern of the second wiring layer M2 for electrically connecting the third pattern M13 and the ninth pattern M19 may extend in the X-axis direction.

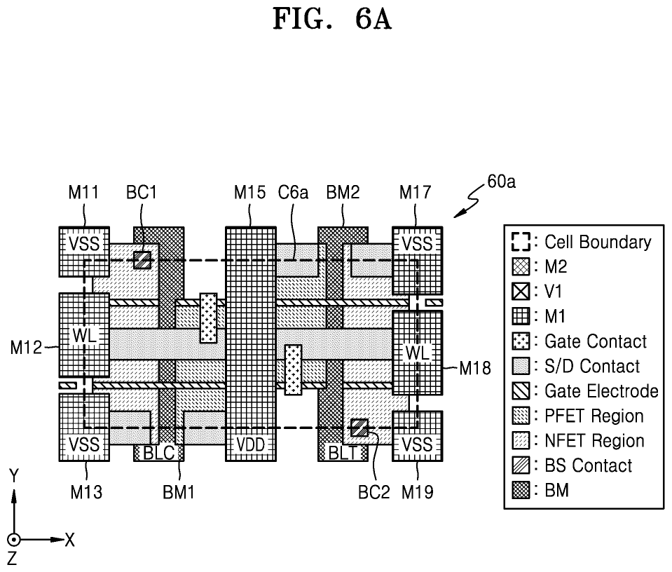

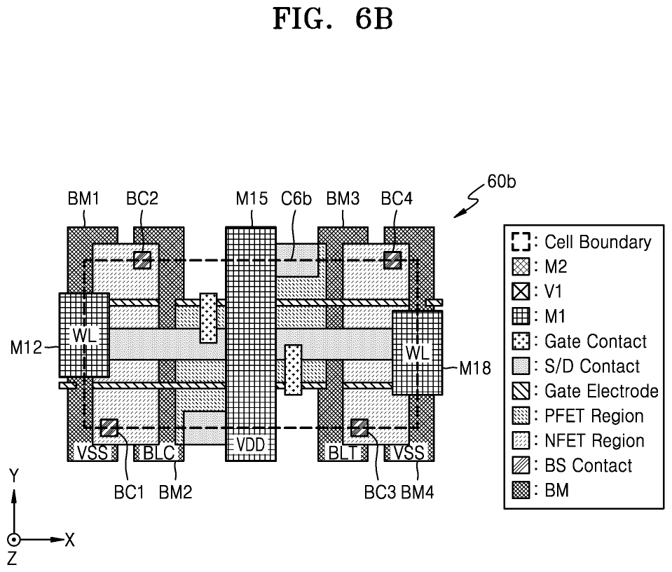

FIGS. 6A and 6B are diagrams showing a layout 60a and a layout 60b of an integrated circuit according to embodiments. For example, the plan views of FIGS. 6A and 6B show the layout 60a and layout 60b of a memory cell Coa and a memory cell C6b corresponding to the equivalent circuit 40 of FIG. 4, respectively. The plan views of FIGS. 6A and 6B show the layout 60a and the layout 60b including patterns of the backside wiring layer BM, backside contacts, NFET regions, PFET regions, gate electrodes, contacts, and patterns of the first wiring layer M1. In FIGS. 6A and 6B, a name written on a pattern indicates a voltage applied to a line to which the pattern is electrically connected and/or the pattern. For convenience of illustration, source/drains and active patterns are omitted in FIGS. 6A and 6B. Hereinafter, FIGS. 6A and 6B will be described with reference to FIG. 4, and descriptions identical to those given above with reference to the drawings may not be repeated.

Referring to FIG. 6A, a layout 60a may include patterns extending in the Y-axis direction in the backside wiring layer BM. For example, as shown in FIG. 6A, a first backside pattern BM1 corresponding to the bit line BLC and a second backside pattern BM2 corresponding to the complementary bit line BLT may extend in the Y-axis direction below a substrate. The first backside contact BC1 may extend in the +Z-axis direction on the first backside pattern BM1, and the second backside contact BC2 may extend in the +Z-axis direction on the second backside pattern BM2. Therefore, patterns (e.g., fourth pattern M14 and sixth pattern M16 of FIG. 5B) respectively corresponding to the bit line BLC and the complementary bit line BLT in the first wiring layer M1 may be omitted.

In a layout 60b of FIG. 6B, the bit line BLC may be free from parasitic capacitances due to the first pattern M11, the second pattern M12, the third pattern M13, and the fifth pattern M15 of the first wiring layer M1. Also, the complementary bit line BLT may be free from parasitic capacitances due to the fifth pattern M15, the seventh pattern M17, the eighth pattern M18, and the ninth pattern M19 of the first wiring layer M1. Also, the fifth pattern M15 of FIG. 5B may have a limited width (i.e., a length in the X-axis direction) due to parasitic capacitances due to the bit line BLC and the complementary bit line BLT. Meanwhile, the fifth pattern M15 of FIG. 6A may have an expanded width and lower parasitic resistance. According to some embodiments, the fifth pattern M15 may overlap the second backside pattern BM2 and a third backside pattern BM3 respectively corresponding to the bit line BLC and the complementary bit line BLT in the Z-axis direction. According to some embodiments, the thickness (i.e., a length in the Z-axis direction) of the backside wiring layer BM may be greater than the thickness of the first wiring layer M1, and thus parasitic resistances of the bit line BLC and the complementary bit line BLT may be reduced.

Referring to FIG. 6B, the layout 60b may include patterns extending in the Y-axis direction in the backside wiring layer BM. For example, as shown in FIG. 6B, the first backside pattern BM1 and a fourth backside pattern BM4 corresponding to the negative supply voltage VSS may extend in the Y-axis direction below the substrate. Also, the second backside pattern BM2 corresponding to the bit line BLC and the third backside pattern BM3 corresponding to the complementary bit line BLT may extend in the Y-axis direction below the substrate. A first backside contact BC1, a second backside contact BC2, a third backside contact BC3, and a fourth backside contact BC4 may extend in the +Z-axis direction on a first backside pattern BM1, a second backside pattern BM2, a third backside pattern BM3, and a fourth backside pattern BM4, respectively. Therefore, patterns (e.g., fourth pattern M14 and sixth pattern M16 of FIG. 5B) respectively corresponding to the bit line BLC and the complementary bit line BLT in the first wiring layer M1 may be omitted. Also, patterns corresponding to the negative supply voltage VSS may extend continuously in the Y-axis direction. In other words, in FIG. 5B, the first pattern M11 and the third pattern M13 corresponding to the negative supply voltage VSS may be separated from the first wiring layer M1 due to the second pattern M12, whereas the first backside pattern BM1 corresponding to the negative supply voltage VSS in FIG. 6B may extend continuously in the Y-axis direction and provide reduced parasitic resistance. Also, in FIG. 5B, the seventh pattern M17 and the ninth pattern M19 corresponding to the negative supply voltage VSS may be separated from the first wiring layer M1 due to the eighth pattern M18, whereas the fourth backside pattern BM4 corresponding to the negative supply voltage VSS in FIG. 6B may extend continuously in the Y-axis direction and provide reduced parasitic resistance. In embodiments, a thickness of each of the first backside pattern BM1 and the fourth backside pattern BM4 in the Z-axis direction may be greater than a thickness of the fifth pattern M15 in the Z-axis direction may be greater than.

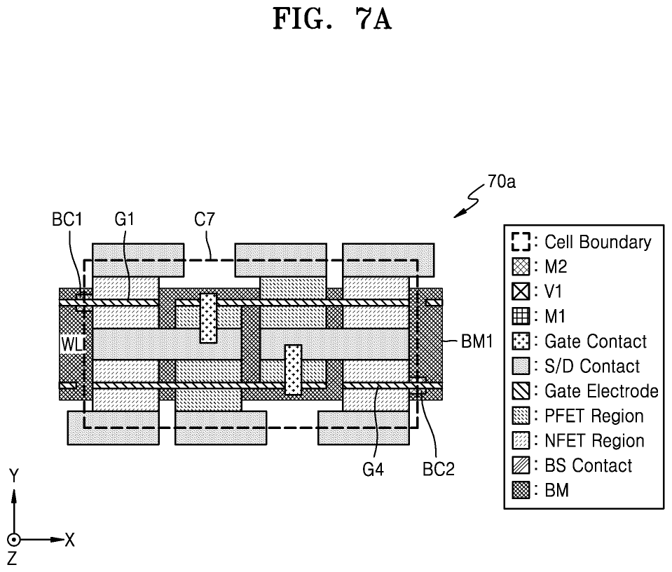

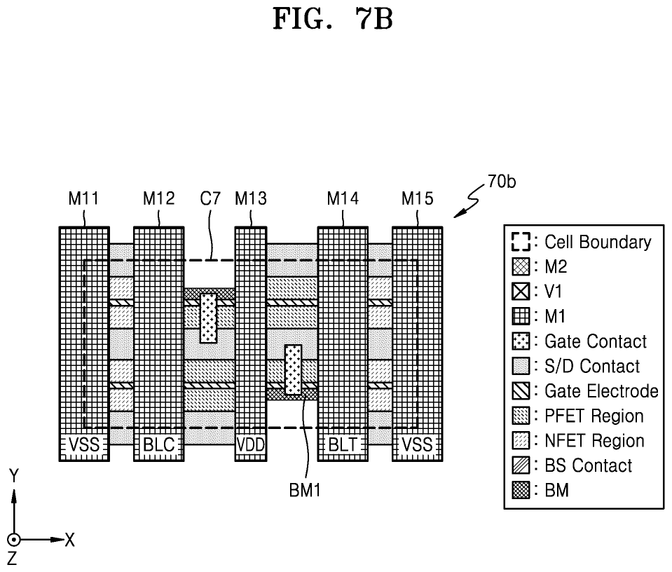

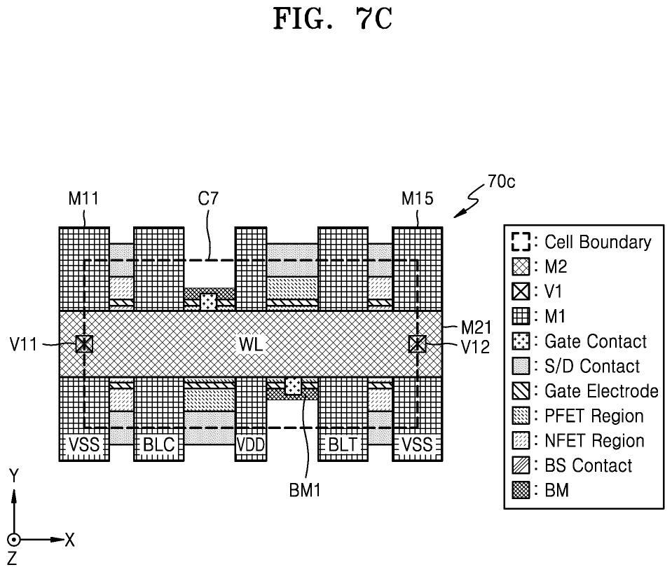

FIGS. 7A to 7C are diagrams showing a layout 70a, a layout 70b, and a layout 70c of an integrated circuit according to embodiments. For example, the plan views of FIGS. 7A to 7C show the layout 70a, the layout 70b, and the layout 70c of a memory cell C7 corresponding to the equivalent circuit 40 of FIG. 4. The plan view of FIG. 7A shows a layout 70a including the backside wiring layer BM, backside contacts, NFET regions, PFET regions, gate electrodes, and contacts, the plan view of FIG. 7B shows a layout 70b further including patterns of the first wiring layer M1 as compared to the layout 70a of FIG. 7A, and the plan view of FIG. 7C shows a layout 70c further including vias of the via layer V1 and patterns of the second wiring layer M2 as compared to the layout 70b of FIG. 7B. In FIGS. 7A to 7C, a name written on a pattern indicates a voltage applied to a line to which the pattern is electrically connected and/or the pattern. For convenience of illustration, source/drains and active patterns are omitted in FIGS. 7A to 7C. Hereinafter, FIGS. 7A to 7C will be described with reference to FIG. 4, and descriptions identical to those given above with reference to the drawings may not be repeated.

Referring to FIG. 7A, the layout 70a may include patterns extending in the X-axis direction in the backside wiring layer BM. For example, as shown in FIG. 7A, the first backside pattern BM1 corresponding to the word line WL may extend in the X-axis direction under the substrate. On the first backside pattern BM1, the first backside contact BC1 may extend in the +Z-axis direction and be connected to the first gate line G1 (e.g., first gate electrode). In other words, the first backside contact BC1 may have a bottom surface connected to the first backside pattern BM1 and a top surface connected to the first gate line G1. Also, on the first backside pattern BM1, the second backside contact BC2 may extend in the +Z-axis direction and be connected to a fourth gate line G4 (e.g., fourth gate electrode). That is, the second backside contact BC2 may have a bottom surface connected to the first backside pattern BM1 and a top surface connected to the fourth gate electrode G4. Accordingly, patterns corresponding to the word line WL (e.g., second pattern M12 and eighth pattern M18 of FIG. 5B) may be omitted in the first wiring layer M1.

As described above with reference to FIGS. 5A to 5C, in the memory cell C5, the first gate line G1 and the fourth gate line G4 may be connected to a pattern of the second wiring layer M2 extending in the X-axis direction (e.g., pattern M21) through gate contacts (e.g., third gate contact CB3 and fourth gate contact CB4), patterns of the first wiring layer (e.g., second pattern M12 and eighth pattern M18), and vias (e.g., first via V11 and second via V12) of the second via layer V1. In the memory cell C7 of FIG. 7A, the first gate line G1 and the fourth gate line G4 may be connected to the first backside pattern BM1 extending in the X-axis direction through the first backside contact BC1 and the second backside contact BC2, and thus the memory cell C7 may be selected by the word line WL having reduced parasitic resistance. According to some embodiments, the thickness (i.e., a length in the Z-axis direction) of the backside wiring layer BM may be greater than the thickness of the first wiring layer M1, and thus parasitic resistance of the word line WL may be reduced.

Referring to FIG. 7B, patterns may extend in the Y-axis direction in the first wiring layer M1. For example, as shown in FIG. 7B, the first pattern M11 and the fifth pattern M15 corresponding to the negative supply voltage VSS may extend in the Y-axis direction. The second pattern M12 and the fourth pattern M14 respectively corresponding to the bit line BLC and the complementary bit line BLT may extend in the Y-axis direction. Also, the third pattern M13 corresponding to the positive supply voltage VDD may extend in the Y-axis direction between the second pattern M12 and the fourth pattern M14. Due to the first backside pattern BM1, patterns corresponding to the word line WL (e.g., second pattern M12 and eighth pattern M18 of FIG. 5B) may be omitted in the first wiring layer M1. Therefore, each of the first pattern M11 and the fifth pattern M15 corresponding to the negative supply voltage VSS may extend continuously in the Y-axis direction between two bit lines adjacent to each other from among the plurality of bit lines and provide reduced parasitic resistance.

Referring to FIG. 7C, patterns may extend in the X-axis direction in the second wiring layer M2. For example, as shown in FIG. 7C, the pattern M21 corresponding to the negative supply voltage VSS may extend in the X-axis direction in the second wiring layer M2. The pattern M21 of the second wiring layer M2 may be electrically connected to the first pattern M11 through the first via V11 of the second via layer V1 and may be electrically connected to the fifth pattern M15 through the second via V12.

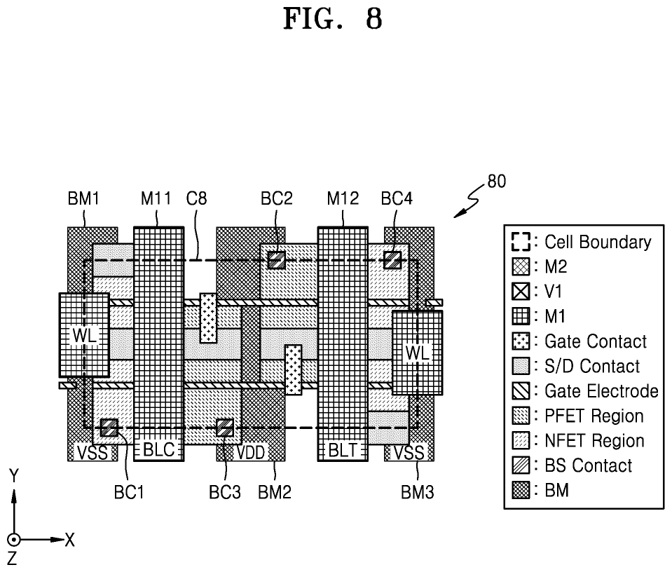

FIG. 8 is a diagram showing a layout 80 of an integrated circuit according to an embodiment. For example, the plan view of FIG. 8 shows the layout 80 of a memory cell C8 corresponding to the equivalent circuit 40 of FIG. 4. The plan view of FIG. 8 shows the layout 80 including the backside wiring layer BM, backside contacts, NFET regions, PFET regions, gate electrodes, contacts, and patterns of the first wiring layer M1. In FIG. 8, a name written on a pattern indicates a voltage applied to a line to which the pattern is electrically connected and/or the pattern. For convenience of illustration, source/drains and active patterns are omitted in FIG. 8. Hereinafter, FIG. 8 will be described with reference to FIG. 4, and descriptions identical to those given above with reference to the drawings may not be repeated.

Referring to FIG. 8, the layout 80 may include patterns extending in the Y-axis direction in the backside wiring layer BM. For example, as shown in FIG. 8, the first backside pattern BM1 and the third backside pattern BM3 corresponding to the negative supply voltage VSS may extend in the Y-axis direction. Also, the second backside pattern BM2 corresponding to the positive supply voltage VDD may extend in the Y-axis direction between the first backside pattern BM1 and the third backside pattern BM3. The first backside contact BC1 may be placed on the first backside pattern BM1, the second backside contact BC2 and a third backside contact BC3 may be placed on the second backside pattern BM2, and a fourth backside contact BC4 may be placed on the third backside pattern BM3.

As shown in FIG. 8, the first backside pattern BM1 and the third backside pattern BM3 may extend continuously in the Y-axis direction, thereby providing reduced parasitic resistance. The second backside pattern BM2 may have a greater width (i.e., a length in the X-axis direction) than the fifth pattern M15 of FIG. 5B, thereby providing reduced parasitic resistance. According to some embodiments, the second backside pattern BM2 may overlap the first pattern M11 and the second pattern M12 respectively corresponding to the bit line BLC and the complementary bit line BLT in the Z-axis direction. According to some embodiments, the thickness (i.e., a length in the Z-axis direction) of the backside wiring layer BM may be greater than the thickness of the first wiring layer M1, and thus the second backside pattern BM2 may provide reduced parasitic resistance. Therefore, due to the second backside pattern BM2, a pattern corresponding to the positive supply voltage VDD (e.g., fifth pattern M15 of FIG. 5B) may be omitted in the first wiring layer M1. Therefore, the parasitic capacitance of the first pattern M11 and the second pattern M12 respectively corresponding to the bit line BLC and the complementary bit line BLT in the first wiring layer M1 may be reduced.

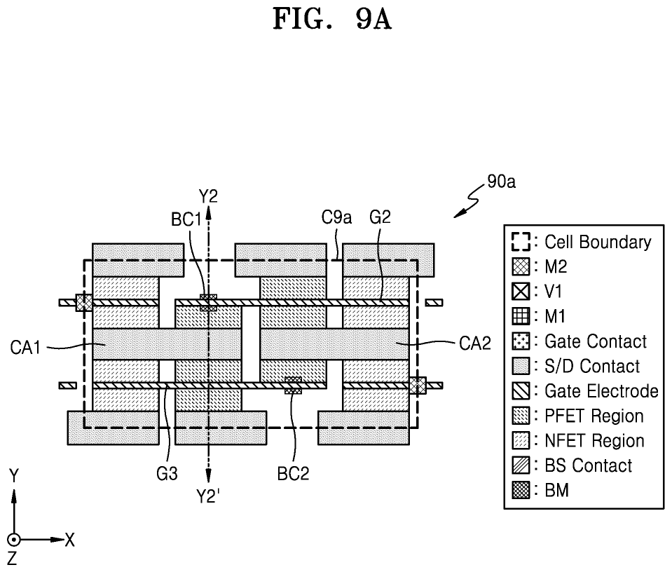

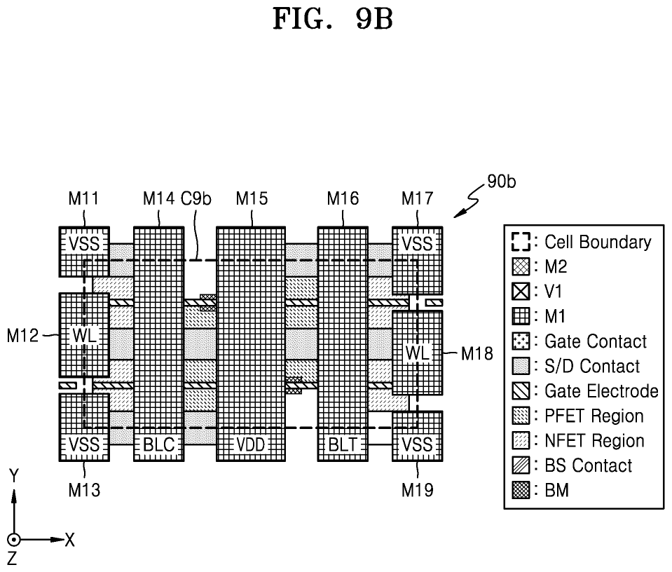

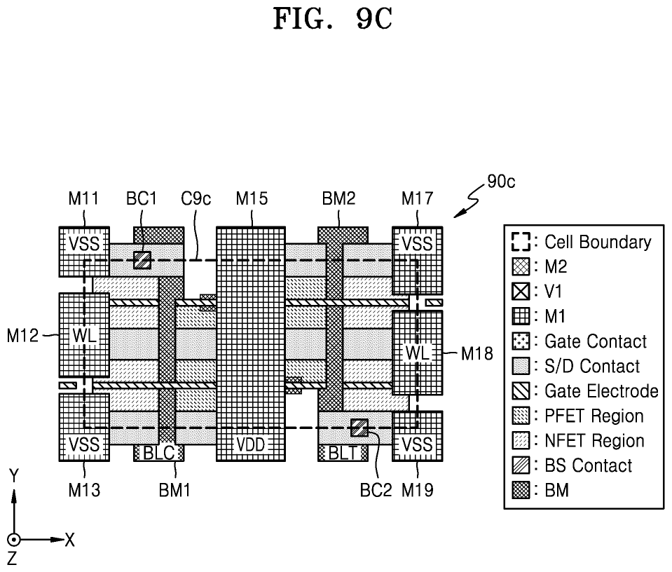

FIGS. 9A to 9C are diagrams showing a layout 90a, a layout 90b, and a layout 90c of an integrated circuit according to embodiments. For example, the plan views of FIGS. 9A to 9C show the layout 90a, the layout 90b, and the layout 90c of a memory cell C9a, a memory cell C9b, and a memory cell C9c corresponding to the equivalent circuit 40 of FIG. 4. The plan view of FIG. 9A shows a layout 90a including NFET regions, PFET regions, gate electrodes, and contacts, the plan view of FIG. 9B shows a layout 90b further including patterns of the first wiring layer M1 as compared to the layout 90a of FIG. 9A, and the plan view of FIG. 9C shows a layout 90c further including patterns of the backside wiring layer BM and the first wiring layer M1 as compared to the layout 90b of FIG. 9B. In FIGS. 9A to 9C, a name written on a pattern indicates a voltage applied to a line to which the pattern is electrically connected and/or the pattern. For convenience of illustration, source/drains and active patterns are omitted in FIGS. 9A to 9C. Hereinafter, FIGS. 9A to 9C will be described with reference to FIG. 4, and descriptions identical to those given above with reference to the drawings may not be repeated.

Referring to FIG. 9A, the layout 90a may include backside contacts electrically connected to the first node N1 and the second node N2 of FIG. 4. For example, as shown in FIG. 9A, the layout 90a may include the first backside contact BC1 corresponding to the first node N1 and the second backside contact BC2 corresponding to the second node N2. The first backside contact BC1 may electrically interconnect the second gate line G2 (e.g., second gate electrode) and the first source/drain contact CA1. The second backside contact BC2 may electrically inter connect the third gate line G3 (e.g., third gate electrode) and the second source/drain contact CA2. Therefore, gate contacts (e.g., first gate contact CB1 and second gate contact CB2 of FIG. 5A) corresponding to the first node N1 and the second node N2 may be omitted. Examples of the first backside contact BC1 will be described later with reference to FIGS. 10A and 10B.

Referring to FIG. 9B, patterns may extend in the Y-axis direction in the first wiring layer M1. For example, as shown in FIG. 9B, a fourth pattern M14 and a sixth pattern M16 respectively corresponding to the bit line BLC and the complementary bit line BLT may extend in the Y-axis direction. A fifth pattern M15 corresponding to the positive supply voltage VDD may extend in the Y-axis direction between the fourth pattern M14 and the sixth pattern M16. Also, a first pattern M11, a third pattern M13, a seventh pattern M17, and a ninth pattern M19 corresponding to the negative supply voltage VSS may extend in the Y-axis direction. The second pattern M12 corresponding to the word line WL may extend in the Y-axis direction between the first pattern M11 and the third pattern M13, and the eighth pattern M18 corresponding to the word line WL may extend in the Y-axis direction between the seventh pattern M17 and the ninth pattern M19.

According to some embodiments, the fifth pattern M15 corresponding to the positive supply voltage VDD may have a greater width (i.e., a length in the X-axis direction) than the fifth pattern M15 of FIG. 5B. For example, as described above with reference to FIG. 9A, gate contacts (e.g., first gate contact CB1 and second gate contact CB2 of FIG. 5A) corresponding to the first node N1 and the second node N2 may be omitted in the layout 90b, and thus the fifth pattern M15 of FIG. 9B may have an expanded width. According to some embodiments, due to omitted gate contacts, the fourth pattern M14 and the sixth pattern M16 respectively corresponding to the bit line BLC and the complementary bit line BLT may have a greater width (i.e., a length in the X-axis direction) than the fourth pattern M14 and the sixth pattern M16 of FIG. 5B.

Referring to FIG. 9C, patterns may extend in the Y-axis direction in the backside wiring layer BM, and patterns may extend in the Y-axis direction in the first wiring layer M1. For example, as shown in FIG. 9C, the first backside pattern BM1 and the second backside pattern BM2 respectively corresponding to the bit line BLC and the complementary bit line BLT may extend in the Y-axis direction. In the first wiring layer M1, the fifth pattern M15 corresponding to the positive supply voltage VDD may extend in the Y-axis direction, and the first pattern M11, the third pattern M13, the seventh pattern M17, and the ninth pattern M19 corresponding to the negative supply voltage VSS may extend in the Y-axis direction. The second pattern M12 corresponding to the word line WL may extend in the Y-axis direction between the first pattern M11 and the third pattern M13, and the eighth pattern M18 corresponding to the word line WL may extend in the Y-axis direction between the seventh pattern M17 and the ninth pattern M19. The first backside contact BC1 may extend in the +Z-axis direction on the first backside pattern BM1, and the second backside contact BC2 may extend in the +Z-axis direction on the second backside pattern BM2. Therefore, patterns (e.g., fourth pattern M14 and sixth pattern M16 of FIG. 9B) respectively corresponding to the bit line BLC and the complementary bit line BLT in the first wiring layer M1 may be omitted.

In the layout 90c of FIG. 9C, the bit line BLC may be free from parasitic capacitances due to the first pattern M11, the second pattern M12, the third pattern M13, and the fifth pattern M15 of the first wiring layer M1. Also, the complementary bit line BLT may be free from parasitic capacitances due to the fifth pattern M15, the seventh pattern M17, the eighth pattern M18, and the ninth pattern M19 of the first wiring layer M1. According to some embodiments, the thickness (i.e., a length in the Z-axis direction) of the backside wiring layer BM may be greater than the thickness of the first wiring layer M1, and thus parasitic resistances of the bit line BLC and the complementary bit line BLT may be reduced. According to some embodiments, the fifth pattern M15 corresponding to the positive supply voltage VDD may have a greater width (i.e., a length in the X-axis direction) than the fifth pattern M15 of FIG. 5B. According to some embodiments, the fifth pattern M15 may overlap the first backside pattern BM1 and the second backside pattern BM2 respectively corresponding to the bit line BLC and the complementary bit line BLT in the Z-axis direction.

FIGS. 10A and 10B are diagrams showing a layout 100a and a layout 100b of an integrated circuit according to embodiments. For example, FIGS. 10A and 10B are cross-sectional views of the layout 90a of FIG. 9A taken along a line Y2-Y2′. As described above with reference to FIG. 9A, the layout 100a and the layout 100b may each include the first backside contact BC1 electrically connected to the first node N1.

Referring to FIG. 10A, the first backside contact BC1 may include a first portion P1 extending in the X-axis direction and a second portion P2 and a third portion P3 extending in the Z-axis direction. For example, as shown in FIG. 10A, the first portion P1 may extend in the X-axis direction below the substrate SUB. The second portion P2 may extend from the first portion P1 to the second gate line G2 (e.g., second gate electrode) through the substrate SUB. The third portion P3 may extend from the first portion P1 to the first source/drain SD1 through the substrate SUB. Therefore, the second gate line G2 and the first source/drain contact CA1 corresponding to the first node N1 may be electrically connected to each other through the first backside contact BC1, and the gate contact (e.g., first gate contact CB1) of FIG. 5A may be omitted.

Referring to FIG. 10B, the first backside contact BC1 may include a first portion P1 extending in the X-axis direction and a second portion P2 and a third portion P3 extending in the Z-axis direction. For example, as shown in FIG. 10B, the first portion P1 may extend in the X-axis direction below the substrate SUB. The second portion P2 may extend from the first portion P1 to the second gate electrode G2 through the substrate SUB and active patterns. According to some embodiments, an insulation layer may be disposed between the second portion P2 and the active patterns. The third portion P3 may extend from the first portion P1 to the first source/drain contact CA1 through the substrate SUB and the active patterns (or source/drains). According to some embodiments, an insulation layer may be disposed between the second portion P2 and the active patterns (or source/drains). Therefore, the second gate electrode G2 and the first source/drain contact CA1 corresponding to the first node N1 may be electrically connected to each other through the first backside contact BC1, and the gate contact (e.g., first gate contact CB1) of FIG. 5A may be omitted.

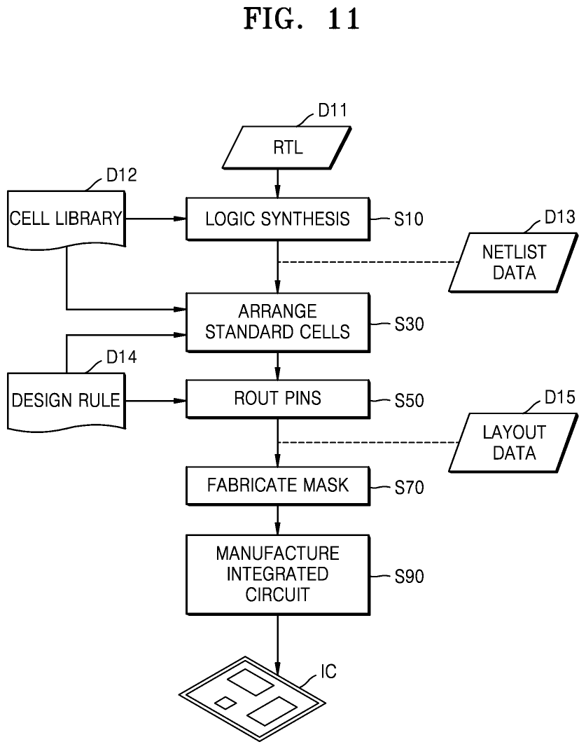

FIG. 11 is a flowchart of a method of manufacturing an integrated circuit IC according to an embodiment. In detail, the flowchart of FIG. 11 shows an example of a method of manufacturing an integrated circuit IC including standard cells. A standard cell is a unit of a layout included in an integrated circuit and may be designed to perform a pre-defined function. As shown in FIG. 11, the method of manufacturing the integrated circuit IC may include a plurality of operations (e.g., operation S10, operation S30, operation S50, operation S70, and operation S90).

A cell library D12 (or a standard cell library) may include information regarding standard cells, e.g., function information, characteristic information, layout information, etc. According to some embodiments, the cell library D12 may define tap cells and dummy cells as well as functional cells that generate an output signal from an input signal. According to some embodiments, the cell library D12 may define memory cells and dummy cells having the same footprint, that is, the same length in the X-axis direction and the Y-axis direction.

Design rules D14 may include conditions that the layout of the integrated circuit IC need to comply with. For example, the design rules D14 may include conditions regarding spaces between patterns, the minimum width of the patterns, a routing direction of a wiring layer, etc. in the same layer. In some embodiments, the design rules D14 may define the minimum separation distance within the same track of a wiring layer.

In operation S10, a logical synthesis operation for generating netlist data D13 from RTL data D11 may be performed. For example, a semiconductor design tool (e.g., a logical synthesis tool) may perform a logical synthesis with reference to the cell library D12 from the RTL data D11 composed in a VHSIC Hardware Description Language (VHDL) and a Verilog and generate the netlist data D13 including a bitstream or a netlist. The netlist data D13 may correspond to input of place and routing, which will be described later.

In operation S30, standard cells may be arranged. For example, a semiconductor design tool (e.g., a P&R tool) may arrange (or place) standard cells used in the netlist data D13 with reference to the cell library D12. According to some embodiments, a semiconductor design tool may place standard cells in a row extending in an X-axis direction or a Y-axis direction, and placed standard cells may receive power from power rails extending along boundaries of the row.

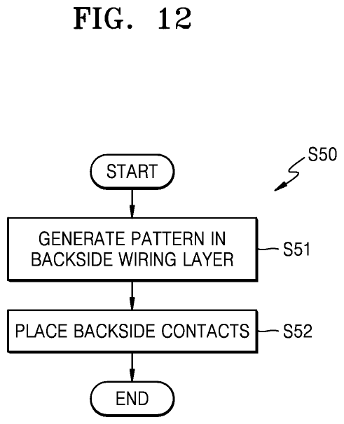

In operation S50, pins of standard cells may be routed. For example, the semiconductor design tool may generate interconnections electrically connecting output pins and input pins of arranged standard cells and generate layout data D15 defining the arranged standard cells and the interconnections. An interconnection may include vias of a via layer and/or patterns of wiring layers. The wiring layers may include a backside wiring layer located below a gate electrode as well as a wiring layer located above the gate electrode like the first wiring layer M1. The layout data D15 may have a format like GDSII and may include geometric information regarding cells and interconnections. The semiconductor design tool may refer to the design rules D14 while routing pins of cells. The layout data D15 may correspond to the output of place and routing. An example of operation S50 will be described later with reference to FIG. 12. Operation S50 may alone be referred to as a method of designing an integrated circuit or operation S30 and operation S50 may collectively be referred to as a method for designing an integrated circuit.

In operation S70, an operation for fabricating a mask may be performed. For example, optical proximity correction (OPC) for correcting distortions due to characteristics of light (e.g., refraction) in photolithography may be applied to the layout data D15. Patterns on the mask may be defined to form patterns to be arranged in a plurality of layers based on OPC-applied data, and at least one mask (or photomask) for forming patterns of each of the layers may be manufactured. In some embodiments, the layout of the IC may be limitedly modified in operation S70, and the limited modification of the IC in operation S70 is a post-processing for optimizing the structure of the IC and may be referred to as design polishing.

In operation S90, an operation for manufacturing the integrated circuit IC may be performed. For example, the integrated circuit IC may be manufactured by patterning the plurality of layers by using the at least one mask fabricated in operation S70. A front-end-of-line (FEOL) may include, for example, planarizing and cleaning the wafer, forming a trench, forming a well, forming a gate electrode, and forming a source and a drain. Individual devices such as a transistor, a capacitor, and a resistor may be formed on a substrate through the FEOL. Also, for example, a back-end-of-line (BEOL) may include operations like silicidation of a gate, a source region, and a drain region, adding a dielectric, planarizing, forming holes, adding metal layers, forming vias, and forming a passivation layer. Individual devices such as a transistor, a capacitor, and a resistor may be connected to one another through the BEOL. In some embodiments, a middle-of line (MOL) may be performed between the FEOL and the BEOL, and contacts may be formed on individual elements. Next, the integrated circuit IC may be packaged in a semiconductor package and used as a component for various applications.

FIG. 12 is a flowchart of a method of designing an integrated circuit according to an embodiment. For example, FIG. 12 is a flowchart showing an example of operation S50 of FIG. 11. As described above with reference to FIG. 11, pins may be routed in operation S50 of FIG. 12. As shown in FIG. 12, operation S50 may include operation S51 and operation S52.

Referring to FIG. 12, a pattern may be formed in a backside wiring layer in operation S51. For example, a semiconductor design tool may use the backside wiring layer as a routing resource for routing pins. Therefore, the backside wiring layer may be used for routing power pins for power supply as well as routing input pins and output pins of standard cells. Due to increased routing resources, routing congestion may be eliminated and interconnections may be simplified, and thus signal paths may be shortened. Also, parasitic elements occurring in routing, such as parasitic resistance and/or parasitic capacitance, may be reduced, and performance and reliability of an integrated circuit may be improved.

In operation S52, a backside contact may be placed. For example, the semiconductor design tool may place a backside contact to connect a pattern of the backside wiring layer generated in operation S51 to a gate electrode, source/drain, and/or a source/drain contact. According to some embodiments, as described above with reference to the drawings, the backside contact may be placed on a memory cell, connect the memory cell to a word line and/or a bit line, or provide the positive supply voltage VDD and/or the negative supply voltage VSS to the memory cell.

FIG. 13 is a block diagram showing a system-on-chip (SoC) 130 according to an embodiment. The SoC 130 may refer to an integrated circuit on which parts of a computing system or other electronic systems are integrated. For example, as an example of the SoC 130, an application processor (AP) may include a processor and parts for other functions. As shown in FIG. 13, the SoC 130 may include a core 131, a digital signal processor (DSP) 132, a graphics processing unit (GPU) 133, an embedded memory 134, a communication interface 135, and a memory interface 136. The components of the SoC 130 may communicate with one another through a bus 137.

The core 131 may process instructions and control operations of the components included in the SoC 130. For example, the core 131 may process a series of instructions, thereby driving an operating system and executing applications on the operating system. The DSP 132 may generate useful data by processing digital signals (e.g., digital signals provided from the communication interface 135). The GPU 133 may generate data for images output through a display device from image data provided from the embedded memory 134 or the memory interface 136 or encode image data. According to some embodiments, the memory device described above with reference to the drawings may be included in the core 131, the DSP 132, and/or the GPU 133 as a cache memory and/or a buffer. Therefore, due to the high reliability and efficiency of the memory device, the core 131, the DSP 132, and/or the GPU 133 may also exhibit high reliability and efficiency.

The embedded memory 134 may store data needed for operations of the core 131, the DSP 132, and the GPU 133. In some embodiments, the embedded memory 134 may include the memory device described above with reference to the drawings. Therefore, the embedded memory 134 may include patterns with low parasitic elements, and, as a result, the operational reliability and efficiency of the SoC 130 may be improved.

The communication interface 135 may provide an interface for a communication network or one-to-one communication. The memory interface 136 may provide an interface for an external memory of the SoC 130, (e.g., a dynamic random access memory (DRAM), a flash memory, etc.).

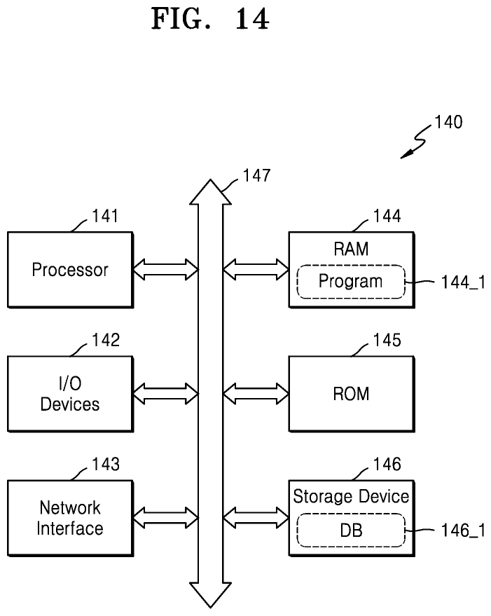

FIG. 14 is a block diagram showing a computing system 140 including a memory storing a program according to an embodiment. At least some of operations included in a method of designing an integrated circuit according to embodiments (e.g., operations of the above-stated flowcharts) may be performed by the computing system 140 (or a computer).

The computing system 140 may be a stationary computing system such as a desktop computer, a workstation, or a server or a portable computing system such as a laptop computer. As shown in FIG. 14, the computing system 140 may include a processor 141, input/output devices 142, a network interface 143, a random access memory (RAM) 144, a read-only memory (ROM) 145, and a storage device 146. The processor 141, the input/output devices 142, the network interface 143, the RAM 144, the ROM 145, and the storage device 146 may be connected to a bus 147 and may communicate with one another through the bus 147.

The processor 141 may be referred to as a processing unit and, for example, may include at least one core (e.g., a micro-processor, an application processor (AP), a digital signal processor (DSP), a graphics processing unit (GPU), etc.) capable of executing an arbitrary instruction set (e.g., Intel Architecture-32 (IA-32), 64-bit extended IA-32, x86-64, PowerPC, Sparc, MIPS, ARM, IA-64, etc.). For example, the processor 141 may access a memory, that is, the RAM 144 or the ROM 145, through the bus 147 and may execute instructions stored in the RAM 144 or the ROM 145.

The RAM 144 may store a program 144_1 for a method of designing an integrated circuit according to an embodiment or at least a portion of the program 144_1, and the program 144_1 may instruct the processor 141 to perform at least some of operations included in the methods of designing an integrated circuit (e.g., the method of FIG. 11). In other words, the program 144_1 may include a plurality of instructions that may be executed by the processor 141, and the instructions included in the program 144_1 may instruct the processor 141 to perform at least some of operations included in the above-stated flowcharts, for example.

The storage device 146 may not lose stored data even when power supplied to the computing system 140 is cut off. For example, the storage device 146 may include a non-volatile memory device or a storage medium such as a magnetic tape, an optical disk, or a magnetic disk. Also, the storage device 146 may be detachable from the computing system 140. The storage device 146 may store the program 144_1 according to an embodiment, and, before the program 144_1 is executed by the processor 141, the program 144_1 or at least a part thereof may be loaded to the RAM 144. Alternatively, the storage device 146 may store a file written in a program language, and the program 144_1 generated from the file by a compiler or the like or at least a part of the program 144_1 may be loaded to the RAM 144. Also, as shown in FIG. 14, the storage device 146 may store a database 146_1, and the database 146_1 may include information needed for designing an integrated circuit (e.g., information regarding designed blocks, the cell library D12, and/or the design rules D14 of FIG. 11).

The storage device 146 may store data to be processed by the processor 141 or data processed by the processor 141. In other words, the processor 141 may generate data by processing data stored in the storage device 146 according to the program 144_1 and may store generated data in the storage device 146. For example, the storage device 146 may store the RTL data D11, the netlist data D13, and/or the layout data D15 of FIG. 11.

The input/output devices 142 may include an input device such as a keyboard and a pointing device and may include an output device such as a display device and a printer. For example, through the input/output devices 142, a user may trigger execution of the program 144_1 through the processor 141, input the RTL data D11 and/or the netlist data D13 of FIG. 11, or check the layout data D15 of FIG. 11.

The network interface 143 may provide access to a network outside the computing system 140. For example, a network may include a plurality of computing systems and communication links, and the communication links may include wired links, optical links, wireless links, or any other types of links.

While non-limiting example embodiments of the present disclosure have been particularly shown and described, it will be understood that various changes in form and details may be made therein without departing from the spirit and scope of the present disclosure.

1. An integrated circuit comprising:
a memory cell array;
a plurality of gate electrodes extending in a first direction above a substrate;
a plurality of word lines extending in the first direction above the substrate;
a plurality of bit lines extending below the substrate in a second direction intersecting the first direction; and
a plurality of first contacts passing through the substrate in a vertical direction and respectively connected to the plurality of bit lines.

2. The integrated circuit of claim 1, further comprising:
a plurality of first power lines extending below the substrate in the second direction and configured to receive a first supply voltage; and
a plurality of second contacts passing through the substrate in the vertical direction and respectively connected to the plurality of first power lines,
wherein each of the plurality of first power lines is continuous in the memory cell array.

3. The integrated circuit of claim 2, further comprising a plurality of second power lines extending above the substrate in the second direction and configured to receive a second supply voltage,
wherein each of the plurality of second power lines is continuous in the memory cell array.

4. The integrated circuit of claim 3, wherein a thickness of each of the plurality of first power lines in the vertical direction is greater than a thickness of each of the plurality of second power lines in the vertical direction.

5. The integrated circuit of claim 1, wherein the plurality of bit lines comprises a plurality of first bit lines and a plurality of second bit lines arranged alternately in the first direction,
wherein the memory cell array comprises a plurality of memory cells, and
wherein each of the plurality of memory cells is electrically connected to one of the plurality of first bit lines, one of the plurality of second bit lines, and one of the plurality of word lines.

6. The integrated circuit of claim 5, wherein each of the plurality of memory cells comprises a plurality of transistors comprising at least one of the plurality of gate electrodes, and
wherein the plurality of transistors comprises:
a first transistor, a second transistor, a third transistor, and a fourth transistor that are configured as a first inverter and a second inverter that are cross-coupled;
a fifth transistor electrically connected to the first inverter, the second inverter, and one of the plurality of first bit lines; and
a sixth transistor electrically connected to the first inverter, the second inverter, and one of the plurality of second bit lines.

7. An integrated circuit comprising:
a memory cell array;
a plurality of gate electrodes extending in a first direction above a substrate;
a plurality of bit lines extending above the substrate in a second direction intersecting the first direction;
a plurality of word lines extending in the first direction below the substrate; and
a plurality of contacts passing through the substrate in a vertical direction and respectively connected to the plurality of gate electrodes and the plurality of word lines.

8. The integrated circuit of claim 7, further comprising:
a plurality of first power lines extending above the substrate in the second direction and configured to receive a first supply voltage; and
a plurality of second power lines extending above the substrate in the second direction and configured to receive a second supply voltage,
wherein each of the plurality of first power lines and the plurality of second power lines is continuous in the memory cell array.

9. The integrated circuit of claim 8, further comprising a plurality of third power lines extending in the second direction above the plurality of first power lines and the plurality of second power lines and configured to receive the first supply voltage,
wherein each of the plurality of third power lines is continuous in the memory cell array.

10. The integrated circuit of claim 9, wherein a thickness of each of the plurality of word lines in the vertical direction is greater than a thickness of each of the plurality of third power lines in the vertical direction.

11. The integrated circuit of claim 8, wherein each of the plurality of first power lines and the plurality of second power lines extends in the second direction between two bit lines adjacent to each other from among the plurality of bit lines.

12. The integrated circuit of claim 7, wherein the plurality of bit lines comprises a plurality of first bit lines and a plurality of second bit lines arranged alternately in the first direction,
wherein the memory cell array comprises a plurality of memory cells, and
wherein each of the plurality of memory cells is electrically connected to one of the plurality of first bit lines, one of the plurality of second bit lines, and one of the plurality of word lines.

13. The integrated circuit of claim 12, wherein each of the plurality of memory cells comprises a plurality of transistors comprising at least one of the plurality of gate electrodes, and
wherein the plurality of transistors comprises:
a first transistor, a second transistor, a third transistor, and a fourth transistor that are configured as a first inverter and a second inverter that are cross-coupled;
a fifth transistor electrically connected to the first inverter, the second inverter, and one of the plurality of first bit lines; and
a sixth transistor electrically connected to the first inverter, the second inverter, and one of the plurality of second bit lines.

14. The integrated circuit of claim 7, wherein each of the plurality of contacts comprises a top surface connected to one of the plurality of gate electrodes and a bottom surface connected to one of the plurality of word lines.

15.-18. (canceled)

19. An integrated circuit comprising:
a memory cell array comprising a plurality of memory cells;
a plurality of gate electrodes extending in a first direction above a substrate;
a plurality of word lines extending in the first direction above the substrate;
a plurality of bit lines extending above the substrate in a second direction intersecting the first direction; and
a plurality of first contacts, each comprising a first portion extending under the substrate in the second direction,
wherein each of the plurality of memory cells included in the memory cell array comprises a first inverter and a second inverter that are cross-coupled with each other at a first node and a second node, and
wherein each of the plurality of first contacts is electrically connected to the first node or the second node.

20. The integrated circuit of claim 19, wherein each of the plurality of first contacts further comprises a second portion and a third portion passing through the substrate in a vertical direction, and
wherein the first portion interconnects the second portion to the third portion.

21. The integrated circuit of claim 20, wherein the second portion comprises a top surface connected to one of the plurality of gate electrodes.

22. The integrated circuit of claim 21, further comprising a plurality of second contacts extending in the first direction above the substrate,
wherein the third portion comprises a top surface connected to one of the plurality of second contacts.

23. The integrated circuit of claim 19, further comprising:
a plurality of first power lines extending below the substrate in the second direction and configured to receive a first supply voltage; and
a plurality of second contacts passing through the substrate in a vertical direction and respectively connected to the plurality of first power lines.

24. The integrated circuit of claim 19, wherein the plurality of bit lines comprises a plurality of first bit lines and a plurality of second bit lines arranged alternately in the first direction, and
wherein each of the plurality of memory cells is electrically connected to one of the plurality of first bit lines, one of the plurality of second bit lines, and one of the plurality of word lines.

25. (canceled)
